(19) United States
(12) Patent Application Publication
(10) Pub. No.: US 2011/0215314 A1
(43) Pub. Date: Sep. 8, 2011

(54) DUAL GATE FIELD-EFFECT TRANSISTOR AND METHOD OF PRODUCING A DUAL GATE FIELD-EFFECT TRANSISTOR

(75) Inventors: Dagobert Michel De Leeuw, Eersel (NL); Paulus Albertus Van Hal, Waalre (NL); Gert 'T Hooft, Eindhoven (NL)

(73) Assignee: KONINKLIJKE PHILIPS ELECTRONICS N.V., Eindhoven (NL)

(21) Appl. No.: 13/126,317

(22) PCT Filed: Oct. 26, 2009
(86) PCT No.: PCT/IB2009/054717

§ 371 Date: Apr. 27, 2011

(30) Foreign Application Priority Data
Oct. 29, 2008 (EP) 08167796.5

(51) Int. Cl. H01L 51/10; H01L 51/40

(52) U.S. Cl. 257/40; 438/99; 257/E51.006; 257/E51.027

(57) ABSTRACT

The present invention relates to a dual gate field-effect transistor (1) comprising a first and a second dielectric layer (6,7), a first and a second gate electrode (9,11) and an assembly (2) of at least one source electrode (3), at least one drain electrode (4) and at least one organic semiconductor (5), wherein—the source electrode (3) and the drain electrode (4) are in contact with the semiconductor (5), the assembly (2) is located between the first dielectric layer (6) and the second dielectric layer (7), the first dielectric layer (6) is located between the first gate electrode (9) and a first side (8) of the assembly (2), and the second dielectric layer (7) is located between the second gate electrode (11) and a second side (10) of the assembly (2), wherein the organic semi-conductor (5) is an organic ambipolar conduction semiconductor (12) which enables at least one electron injection area (18) at the first side (8) and at least one hole injection area (18) at the second side (19) of the assembly (2). The present invention further comprises a corresponding light emission device, a corresponding sensor system and a corresponding memory device comprising at least one field-effect transistor and a method of producing a corresponding dual gate field-effect transistor.

### FIELD OF THE INVENTION

The present invention relates to a dual gate field-effect transistor comprising a first and a second dielectric layer, a first and a second gate electrode and an assembly of at least one source electrode, at least one drain electrode and at least one organic semiconductor, wherein the source electrode and the drain electrode are in contact with the semiconductor, the assembly is located between the first dielectric layer and the second dielectric layer, the first dielectric layer is located between the first gate electrode and a first side of the assembly and the second dielectric layer is located between the second gate electrode and a second side of the assembly.

### BACKGROUND OF THE INVENTION

Document US 2004/0029310 A1 discloses an organic field-effect transistor (OFET) comprising an upper and a lower insulator layer, two gate electrodes and an assembly of a source electrode, a drain electrode and an organic semiconductor, wherein the source electrode and the drain electrode are in contact with the semiconductor. Said assembly is located between the upper and the lower insulating layer, the upper insulating layer being located between the first gate electrode and the assembly and the second dielectric layer being located between the second gate electrode and the assembly. The organic field-effect transistor enables a plurality of independent current channels between the source electrode and the drain electrode with current channel lengths of less than one micron (<1 μm).

### SUMMARY OF THE INVENTION

It is an object of the invention to provide a dual gate field-effect transistor featuring tunable characteristic curves by adjusting the bias voltage applied to the first gate electrode and/or the second gate electrode.

To achieve this object, the organic semiconductor is an organic ambipolar conduction semiconductor which enables at least one electron injection area at the first side and at least one hole injection area at the second side of the assembly. This field-effect transistor enables two charge carrier channels for charge carriers of opposite charge polarity (electrons and holes) within the organic ambipolar conduction semiconductor for ambipolar electrical transport. The channels, an electron transport channel (n-channel) and a hole transport channel (p-channel), run from the source electrode to the drain electrode. The charge carrier channels are preferably laterally layered charge carrier channels. Between the first side and the second side of the assembly a pn-junction is formed. The dual gate field-effect transistor is adapted for generating an additional current component perpendicular to the charge carrier channels, said current component depending on the voltage applied to the gate electrodes. The current component is generated due to (re)combination of the charge carriers of opposite charge polarity. The amplitude of the additional current component is controllable by the bias voltage of at least one of the gate electrodes. The field-effect transistor is adapted for utilization in different applications, like sensor systems, memory devices and light emission devices.

The organic ambipolar conduction semiconductor is preferably an organic ambipolar conduction semiconductor with a calametic liquid crystal structure. A calametic liquid crystal is composed of long, narrow, and substantially rod-shaped organic molecules. The gate electrodes preferably comprise electrode plates of bulk material and/or electrode layers.

According to a preferred embodiment of the invention, the organic ambipolar conduction semiconductor is an organic ambipolar conduction semiconductor film.

Further, according to a preferred embodiment of the invention, the organic ambipolar conduction semiconductor film comprises a first layered region adapted for enabling an electron channel and a second layered region for enabling a hole channel.

According to another preferred embodiment of the invention, the organic ambipolar conduction semiconductor film comprises a first layer adapted for enabling an electron channel and a second layer for enabling a hole channel. The organic ambipolar conduction semiconductor film comprising the first layer and the second layer is an organic ambipolar conduction semiconductor bilayer.

The total thickness of the organic ambipolar conduction semiconductor film preferably is below 20 nm, more preferably below 10 nm. The thickness of the semiconductor film is in the same range as the thickness of the electron injection area and/or the hole injection area.

Further, according to a more preferred embodiment of the invention, the organic ambipolar conduction semiconductor film is formed as an organic semiconductor monolayer or comprises an organic semiconductor monolayer. The organic semiconductor monolayer is preferably an organic ambipolar conduction semiconductor monolayer. The field-effect transistor comprising the organic conduction semiconductor monolayer is preferably a SAMFET (self-assembled monolayer field-effect transistor) comprising a self-assembled monolayer (SAM) for ambipolar conduction.

The organic semiconductor monolayer is a self-assembled monolayer (SAM) spontaneously formed on a substrate. Said substrate is preferably an aggregation of one of the gate electrodes and a corresponding dielectric layer. Tri-chlorosilanes or tri-alkoxysilanes are used as anchoring groups of the SAM. The SAM is formed by a condensation reaction with hydroxyl groups on the hydrolysed substrate surface. In order to prevent defects, mono-functional anchoring groups are crucial. Dimers formed upon self-condensation do not interfere with the self-assembled monolayer on the substrate (gate dielectric). The core of the semiconducting molecule is a thiophene core composed of α-substituted quinquethiophene. The SAM can be modeled as a bi(sub-)layer with two different electron densities. The bottom sub-layer corresponds to an aliphatic chain and the top sub-layer to the thiophene core of the monolayer. The thicknesses of the two sub-layers are fitted to be 1.56 nm (aliphatic chain) and 2.06 nm (thiophene core). The thickness of this monolayer is therefore 3-4 nm. The lateral order of the molecules is caused by intermolecular π-π coupling between the molecules in the self-assembled monolayers.

In general the source electrode and/or the drain electrode are metal electrodes made of the same metal or different metals with different work functions. According to a preferred embodiment of the invention, the source electrode and/or the drain electrode is a gold electrode, preferably a gold electrode layer. The gold source electrode and and/or the gold drain electrode is/are fabricated using conventional photolithographic methods.

According to another preferred embodiment of the invention, the first dielectric layer and/or the second dielectric layer is an organic ferroelectric layer. The dual gate SAMFET then works as a non-volatile memory.

Preferably, the field-effect transistor further comprises at least one transmission window, which enables an emission of light from the organic ambipolar conduction semiconductor to an outer area of the transistor. Radiation or light caused by the recombination of electrons and holes within the organic ambipolar conduction semiconductor can leave the transistor through this window.

Another aspect of the present invention is a light emission device, in particular a laser device, comprising at least one aforementioned dual gate field-effect transistor. The organic ambipolar conduction semiconductor of the dual gate field-effect transistor is an organic ambipolar conduction semiconductor film which enables at least one electron injection area at the first side and at least one hole injection area at the second side of the assembly, wherein the thickness of said organic ambipolar conduction semiconductor film is in the order of the thickness of an accumulation layer, preferably below 10 nm. In particular, the organic ambipolar conduction semiconductor layer is an organic ambipolar conduction semiconductor monolayer, preferably a SAM enabling ambipolar conduction. In order to get lateral charge transport the monolayer is highly ordered and resembles a single crystal as much as possible. Such a device is a self-assembled monolayer field-effect transistor (SAMFET) wherein the ambipolar conduction semiconductor is a monolayer spontaneously formed on the gate dielectric. The light emitting device is preferably a laser device (laser: light amplification by stimulated emission of radiation) further comprising a laser cavity for generating stimulated emission.

A further aspect of the present invention is a sensor system comprising at least one aforementioned dual gate field-effect transistor. The external outer surface of the second dielectric layer comprises receptor molecules capable of bonding to an analyte, preferably selected from the group comprising anion receptors, cation receptors, arene receptors, carbohydrate receptors, lipid receptors, steroid receptors, peptide receptors, nucleotide receptors, RNA receptors and/or DNA receptors. The receptor molecules may be bonded to the surface of the second dielectric layer by covalent, ionic or non-covalent bonds such as Van der Waals interactions.

The analytes which are bonded by the aforementioned receptor molecules represent interesting targets for medical applications. Knowledge of the presence or concentration of these analytes gives valuable insight into the formation or occurrence of diseases. Anions and cations are not limited to simple species like alkaline, alkaline earth, halogenide, sulphate and phosphate but also extend to species like amino acids or carboxylic acids which are formed during metabolic processes in cells. Arene receptors may be employed if the presence of, for example, carcinogenic arenes like polycyclic aromatic hydrocarbons (PAH) is suspected. Carbohydrate receptors may be used in areas like the treatment of diabetes. Lipid receptors may find application if metabolic diseases in connection with adipositas are to be investigated. Steroid receptors which are sensitive to steroid hormones are useful for a wide range of indication areas including pregnancy tests and doping control in commercial sports. The detection of peptides, nucleotides, RNA and DNA is important for the research and treatment of hereditary diseases and cancer.

When an analyte bonds to a receptor molecule, a change in the dipole moment of the receptor molecule can be observed. This in turn leads to a change in the electric field controlling the current between source and drain electrode. Therefore, a signal can be observed and correlated with an analyte. Whereas this behaviour is most easily associated with charged analytes, the detection of non-charged analytes in a surrounding polar medium such as the water of physiological solutions is also possible. When a neutral analyte bonds to the receptor molecule, water molecules are displaced from the receptor molecules or the surface. This results in a change in the dielectric constant of the receptor molecule or the dielectric.

Another aspect of the present invention is a memory device comprising at least one aforementioned dual gate field-effect transistor. Depending on the choice of the materials used and on the geometry, the field-effect transistor can directly be applied as a memory. In a preferred embodiment at least one dielectric layer of the field-effect transistor is chosen as an organic ferroelectric. The dual gate field-effect transistor works as a non-volatile memory.

Yet another aspect of the present invention is a method of producing a dual gate field-effect transistor, said method comprising the following steps:

application of a dielectric layer to a surface of a gate electrode;

application of a source electrode and a drain electrode to the dielectric layer, using at least one photolithographic mask;

activation of the dielectric layer at least in an active region between the source electrode and the drain electrode;

wetting the aggregation of dielectric layer, gate electrode, source electrode and drain electrode with a semiconducting molecule solution for the formation of a self-assembled semiconductor monolayer in the active region;

application of another dielectric layer to the self-assembled semiconductor monolayer; and

application of another gate electrode to the other dielectric layer.

According to a preferred embodiment of the invention, the self-assembled semiconductor monolayer is a self-assembled ambipolar conduction semiconductor monolayer.

The application of the dielectric layers, the source electrode, the drain electrode and/or gate electrode is preferably performed using thermal growing/evaporation or sputtering.

At least one of the dielectric layers is preferably a SiO₂ layer, which is thermally grown on the gate electrode. Said gate electrode is preferably a doped Si single crystal (wafer). The source electrode and/or the drain electrode is a gold electrode, especially a gold layer (gold contact layer). The surface of the dielectric layer in the active region is preferably activated by an oxygen plasma treatment followed by acid hydrolysis.

According to a preferred embodiment of the invention, the wetting of the aggregation is done by submerging the substrate into a dry toluene solution of the semiconducting molecules. After the formation of the self-assembled semiconductor monolayer, the substrate is thoroughly rinsed and dried.

In the case of a film formed as an organic ambipolar conduction semiconductor monolayer based on thiophene, the other dielectric layer is preferably built as a thin film of polyisobutylmonoacrylate (PIBMA), wherein the thickness of the thin film is preferably between 300 nm and 600 nm. In the case of a film comprising an organic conduction semiconductor monolayer and a second thin layer (in particular a thin perylene layer), said thin layer covering the organic ambipolar conduction semiconductor monolayer, an orthogonal solvent is used to form the other dielectric. In this case a fluorinated solvent like FC40 is appropriate.

### BRIEF DESCRIPTION OF THE DRAWINGS

These and other aspects of the invention will be apparent from and elucidated with reference to the embodiments described hereinafter.

In the drawings:

FIG. 1 shows a vertical sectional view of the schematic device geometry of a dual gate field-effect transistor according to the invention;

FIG. 2 shows the chemical structure of a self-assembled semiconductor monolayer (SAM) and the transfer curves of a self-assembled semiconductor monolayer field-effect transistor (SAMFET) according to a first embodiment of the invention;

FIG. 3 shows the transfer curves of a dual gate self-assembled semiconductor monolayer field-effect transistor (SAMFET) for different bias voltages applied to the second gate electrode versus the bias voltage applied to the first gate electrode; and

FIG. 4 shows the transfer curves of a dual gate self-assembled semiconductor monolayer field-effect transistor (SAMFET) for different bias voltages applied to the first gate electrode versus the bias voltage applied to the second gate electrode.

### DETAILED DESCRIPTION OF EMBODIMENTS

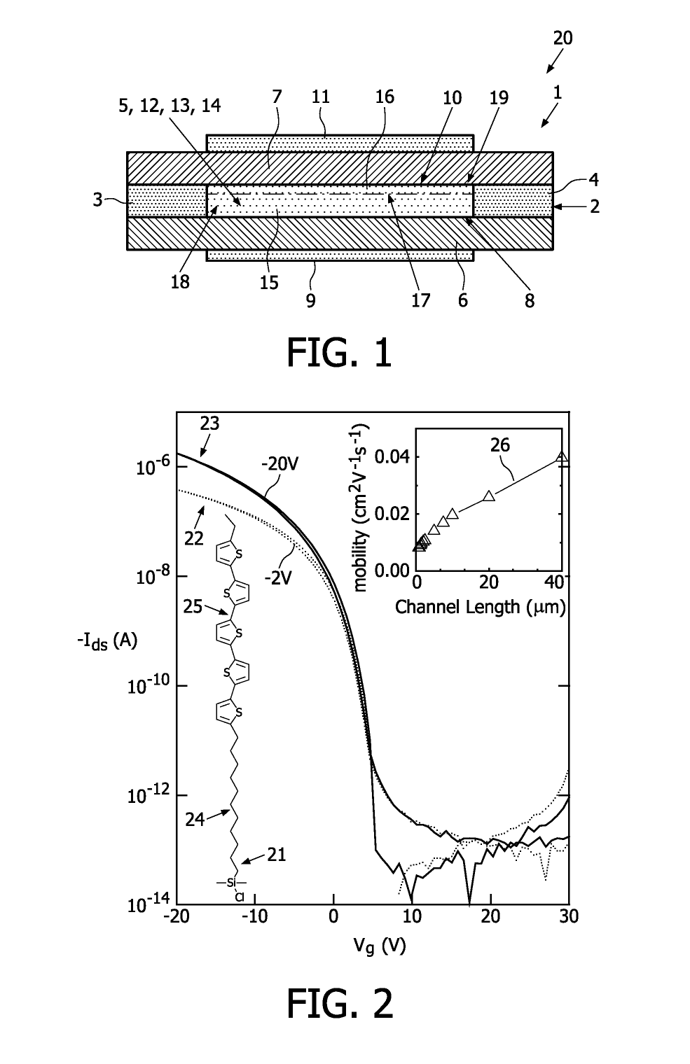

FIG. 1 shows a dual gate field-effect transistor 1 according to the present invention, comprising an assembly 2 of a source electrode 3, a drain electrode 4 and an organic semiconductor 5. Within the assembly 2, the source electrode 3 and the drain electrode 4 are in contact with said semiconductor 5. The assembly 2 is located between first dielectric layer 6 and second dielectric layer 7. The first dielectric layer 6 is located underneath a first side (bottom side in FIG. 1) 8 of the assembly 2 between a first gate electrode 9 and the assembly 2. The second dielectric layer 7 is located on top of a second side (upper side in FIG. 1) 10 of the assembly 2 between the second gate electrode 11 and the assembly 2. The organic semiconductor 5 is an organic ambipolar conduction semiconductor 12 formed as an organic ambipolar conduction semiconductor film 13, more precisely an organic ambipolar conduction self-assembled semiconductor monolayer 14. The organic ambipolar conduction semiconductor film 13 consists of two layered regions 15, 16 divided by a boundary plane 17. The first layered region 15 (bottom region in the embodiment of FIG. 1) enables an electron injection area 18 at the first side 8 of the assembly 2 and the second layered region 16 (upper region in the embodiment of FIG. 1) enables a hole injection area 19 at the second side 10 of the assembly 2. Alternatively the bottom region is the second layered region 16 enabling the hole injection area 19 and the upper region is the first layered region 15 enabling an electron injection area 18. Between the regions 15, 16 at the boundary plane 17 a pn-junction is formed.

Preferably, the second dielectric layer 7 is formed as a dielectric SiO₂ layer. Problems of charge trapping are minimized in this configuration and the holes and electrons can move through the organic ambipolar conduction semiconductor 12 with minimum problems caused by the dielectric layers 6, 7.

The field effect transistor shown in FIG. 1 is preferably used in a light emission device 20 according to the invention. The organic ambipolar conduction semiconductor 12 enables an injection of electrons at the bottom side (first side 8) and holes at the top side (second side 10). The thickness of charge carrier accumulation areas is in the order of the thickness of the organic ambipolar conduction semiconductor film 13. In this case, a bias voltage applied to the gate electrodes 9, 11 leads to electron injection into the electron injection area 18 at the first side 8 of the assembly 2 and hole injection into the hole injection area 19 at the second side 10 of the assembly 2. As the thickness of the organic ambipolar conduction semiconductor film 13 is below 10 nm, the wave functions of the electrons and holes accumulated on both sides 8, 10 of the semiconductor film 13 overlap and the electrons and holes can recombine with one another. This recombination is a radiative recombination. By increasing the biasing voltage between the gate electrodes 9, 11, the density of the injected charge carrier (electrons and holes) can be increased, leading to stimulated emission of light. Therefore, the field-effect transistor 1 with an organic ambipolar conduction semiconductor film 13 having a thickness of less than 10 nm can be used for light emission and even to perform light amplification by stimulated emission of radiation (laser).

A prerequisite for light generation is that the wave functions of the electrons and holes accumulated at both sides of the assembly 2 overlap. This means that the thickness of the organic ambipolar conduction semiconductor 12 should be on the order of the thickness of the accumulation layer. The thickness of this layer is in the order of a few nanometres (nm). In order to get lateral charge transport the monolayer should be highly ordered. It should resemble a single crystal as much as possible.

According to a preferred embodiment of the invention, the dual gate field-effect transistor is the self-assembled monolayer field-effect transistor. This is a field-effect transistor where the semiconductor is a monolayer spontaneously formed on one of the dielectric layers. Hence, the first step is fabrication of functional SAMFETs. The next step is the fabrication of a second gate dielectric and a second gate electrode on the opposite side to form a dual gate.

The method of producing the dual gate SAMFET comprises the following steps:

application of a dielectric SiO₂ layer to a surface of a gate electrode 9,11;

application of a gold source electrode (layer) 3 and a gold drain electrode (layer) 4 to the dielectric SiO₂ layer, using at least one photolithographic mask;

activation of the dielectric layer 6, 7 at least in an active region between the source electrode 3 and the drain electrode 4 by an oxygen plasma treatment followed by acid hydrolysis;

submersion of the aggregation of dielectric layer 6, 7, gate electrode 9, 11, source electrode 3 and drain electrode 4 into a dry toluene solution of the semiconducting molecules for formation of a self-assembled ambipolar conduction semiconductor monolayer in the active region;

application of another dielectric layer 7, 6 to the self-assembled ambipolar conduction semiconductor monolayer 14, wherein said other dielectric layer 7, 6 is preferably built as a thin film of polyisobutylmonoacrylate (PIBMA) and wherein the thickness of the thin film is preferably between 300 nm and 600 nm, and

application of another gate electrode 11, 9, preferably a gold gate electrode, to the other dielectric layer.

The chemical notation 21 (chemical structure) of the semiconducting molecules and the transfer curves 22, 23 of a typical self-assembled organic ambipolar conduction semiconductor monolayer 14 of a dual gate SAMFET (self-assembled monolayer field-effect transistor) are presented in FIG. 2. The diagram shows the transfer curves 22, 23 (drain-source current I_{ds} versus the gate voltage V_{g1} applied to the first gate electrode 9) of a SAMFET with a constant channel length of forty microns (40 μm) and a channel width of one thousand microns (1000 μm). The first transfer curve 22 represents the transfer characteristic using a drain bias voltage of −2 volts (−2V) and the second transfer curve 23 represents the transfer characteristic using a drain bias voltage of −20 volts (−20V).

The first inset on the left side of FIG. 2 shows the chemical notation 21 of one organic molecule of the ambipolar conduction self-assembled monolayer formation. The bottom part is an aliphatic chain 24 and the top part is a thiophene core element 25. The plurality of parallel oriented molecules with their aliphatic chains 24 and thiophene core elements 25 form the ambipolar conduction self-assembled monolayer 14 (calametic liquid crystal).

The second inset on the right side shows a graph 26 representing the linear mobility of the charge carriers (electrons and holes) as a function of the channel length between source electrode 3 and drain electrode 4 in the region of 0 to 40 microns (0-40 μm).

FIG. 3 shows the transfer curves of the dual gate self-assembled semiconductor monolayer field-effect transistor (SAMFET) for different bias voltages applied to the second gate electrode 11 versus the bias voltage applied to the first gate electrode 9 (dual gate SAMFET bottom gate is swept). The bias applied to the second gate electrode 11 is fixed from left to right from 20 to −20 V in steps of 10 V (volts).

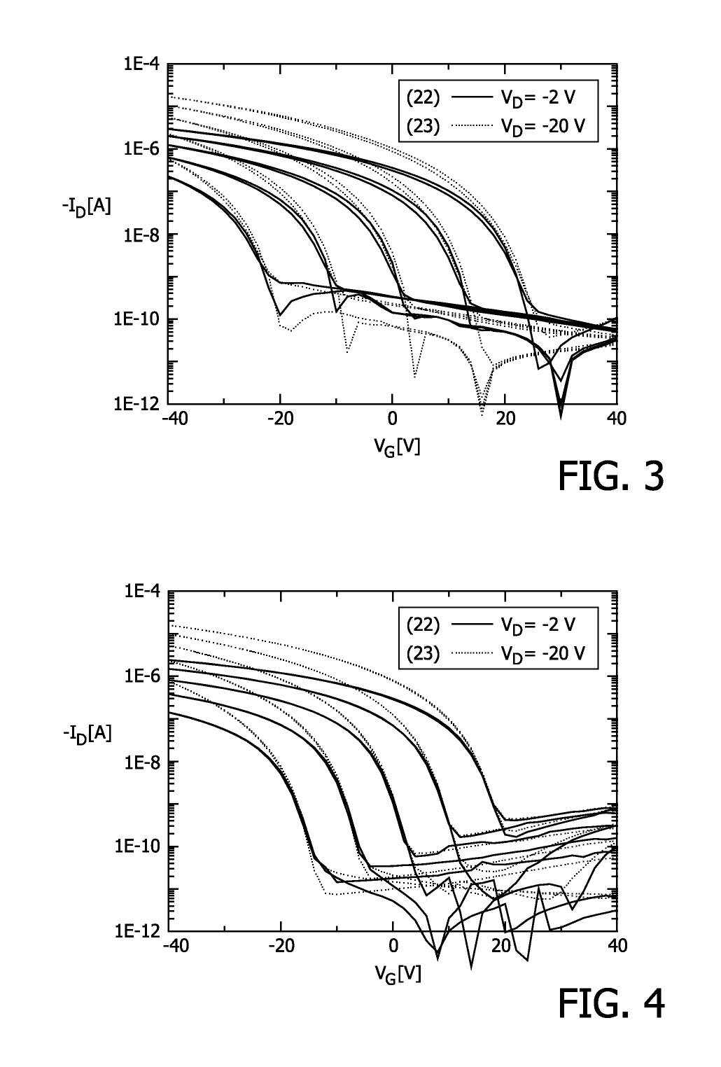

FIG. 4 shows the transfer curves of the dual gate self-assembled semiconductor monolayer field-effect transistor (SAMFET) for different bias voltages applied to the first gate electrode 9 versus the bias voltage applied to the second gate electrode 11 (dual gate SAMFET top gate is swept). The bias applied to the first gate electrode 9 is fixed from left to right from 20 to −20 V in steps of 10 V.

FIGS. 3 and 4 support the fact that the transport of holes and electrons can be modulated by the two gates separately. So the current-voltage-(I-V)-characteristics for both channels, i e the hole channel and the electron channel, can be tuned. This is ideal to get maximum charge recombination. This is important in order to get emission, even amplified stimulated emission.

While the invention has been illustrated and described in detail in the drawings and foregoing description, such illustration and description are to be considered illustrative or exemplary and not restrictive; the invention is not limited to the disclosed embodiments.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

1. Dual gate field-effect transistor (1) comprising a first and a second dielectric layer (6,7), a first and a second gate electrode (9,11) and an assembly (2) of at least one source electrode (3), at least one drain electrode (4) and at least one organic semiconductor (5), wherein
the source electrode (3) and the drain electrode (4) are in contact with the semiconductor (5),
the assembly (2) is located between the first dielectric layer (6) and the second dielectric layer (7),
the first dielectric layer (6) is located between the first gate electrode (9) and a first side (8) of the assembly (2), and
the second dielectric layer (7) is located between the second gate electrode (11) and a second side (10) of the assembly (2),
characterized in that the organic semiconductor (5) is an organic ambipolar conduction semiconductor (12) which enables at least one electron injection area (18) at the first side (8) and at least one hole injection area (18) at the second side (19) of the assembly (2).

2. Field effect transistor (1) according to claim 1, wherein the organic ambipolar conduction semiconductor (12) is an organic ambipolar conduction semiconductor film (13).

3. Field effect transistor (1) according to claim 2, wherein the organic ambipolar conduction semiconductor film (13) comprises a first layered region (15) adapted for enabling an electron channel and a second layered region (16) for enabling a hole channel.

4. Field effect transistor (1) according to claim 2, wherein the organic ambipolar conduction semiconductor film (13) comprises a first layer adapted for enabling an electron channel and a second layer for enabling a hole channel.

5. Field effect transistor (1) according to claim 2, wherein the thickness of the organic semiconductor film (13) is below 20 nm, preferably below 10 nm.

6. Field effect transistor (1) according to claim 2, wherein the organic ambipolar conduction semiconductor film (13) is an organic semiconductor monolayer or comprises an organic semiconductor monolayer.

7. Field effect transistor (1) according to claim 6, wherein the organic semiconductor monolayer is a self-assembled semiconductor monolayer (14).

8. Field effect transistor (1) according to claim 1, wherein the first dielectric layer (6) and/or the second dielectric layer (7) is an organic ferroelectric layer.

9. Field effect transistor (1) according to claim 1, wherein said transistor (1) further comprises at least one transmission window, which enables an emission of light from the ambipolar conduction semiconductor (12).

10. Light emission device (20), in particular a laser device, comprising at least one field effect transistor (1) according to claim 1.

11. Sensor system comprising at least one field effect transistor (1) according to claim 1.

12. Memory device comprising at least one field effect transistor (1) according to claim 1.

13. Method of producing a dual gate field-effect transistor (1), comprising the steps:
application of a dielectric layer (6,7) to a surface of a gate electrode (9,11);
application of a source electrode (3) and a drain electrode (4) to the dielectric layer (6,7), using at least one photolithographic mask;
activation of the dielectric layer (6,7) at least in an active region between the source electrode (3) and the drain electrode (4);
wetting the aggregation of dielectric layer (6,7), gate electrode (9,11), source electrode (3) and drain electrode (4) with a semiconducting molecule solution for the formation of a self-assembled semiconductor monolayer (14) in the active region;
application of another dielectric layer (7,6) to the self-assembled semiconductor monolayer (14); and
application of another gate electrode (11,9) to the other dielectric layer (7,6).

14. Method according to claim 13, wherein the surface of the dielectric layer (6, 7) in the active region is preferably activated by an oxygen plasma treatment followed by acid hydrolysis.

15. Method according to claim 13, wherein the wetting of the aggregation is done by submerging the aggregation into the semiconducting molecule solution.
